(19) United States
(12) Patent Application Publication
(10) Pub. No.: US 2025/0287710 A1
(43) Pub. Date: Sep. 11, 2025

(54) DETECTION DEVICE

(71) Applicant: Japan Display Inc., Tokyo (JP)

(72) Inventors: Hiroki SUGIYAMA, Tokyo (JP); Yoshihide OHUE, Tokyo (JP); Kosuke TAKASU, Tokyo (JP); Takahiro SHOJI, Tokyo (JP); Kaoru TAKETA, Tokyo (JP); Hiroshi INAMURA, Tokyo (JP)

(73) Assignee: Japan Display Inc., Tokyo (JP)

(21) Appl. No.: 19/071,856

(22) Filed: Mar. 6, 2025

(30) Foreign Application Priority Data
Mar. 7, 2024 (JP) 2024-034877

(51) Int. Cl. H10F 39/00

(52) U.S. Cl. CPC H10F 39/8037

(57) ABSTRACT

A detection device includes: a substrate; a switching element that includes a source electrode, a drain electrode, a semiconductor film, and a gate electrode; a first insulating film disposed between the gate electrode and the semiconductor film; a second insulating film that is disposed on the first insulating film, and includes a first contact hole overlapping a portion of the semiconductor film in plan view; and a sensor element electrically coupled to the drain electrode, wherein a first electrode, which is one electrode of the source electrode and the drain electrode, overlaps the gate electrode in plan view and is electrically coupled to the semiconductor film in the first contact hole, and in the first contact hole, the first electrode and the semiconductor film face a first partial surface on a side surface of the first contact hole while being separated from the first partial surface.

### CROSS-REFERENCE TO RELATED APPLICATION

This application claims the benefit of priority from Japanese Patent Application No. 2024-034877 filed on Mar. 7, 2024, the entire contents of which are incorporated herein by reference.

### BACKGROUND

### 1. Technical Field

The present disclosure relates to a detection device.

### 2. Description of the Related Art

Japanese Patent Application Laid-open Publication No. 2023-150465 (JP-A-2023-150465) discloses a display device that includes a switching element electrically coupled to each of a plurality of pixel electrodes. In the switching element, a gate electrode overlaps a source electrode in plan view of the display device. In the switching element, the gate electrode also overlaps a drain electrode in plan view of the display device.

The switching element of JP-A-2023-150465 may be applied to a detection device that includes a plurality of sensor elements. The switching element is electrically coupled to the sensor element. In this case, noise generated by capacitance between the gate electrode and the source electrode or capacitance between the gate electrode and the drain electrode in the switching element may affect the sensor element.

For the foregoing reasons, there is a need to reduce effects of noise on a sensor element in a detection device including a switching element electrically coupled to the sensor element.

### SUMMARY

In some embodiments, a detection device includes: a substrate; a switching element disposed on the substrate, the switching element including a source electrode, a drain electrode, a semiconductor film electrically coupled to the source and the drain electrodes, and a gate electrode disposed on an opposite side of the source and the drain electrodes with the semiconductor film interposed between the gate electrode and the source and the drain electrodes; a first insulating film disposed between the gate electrode and the semiconductor film; a second insulating film that is disposed on the first insulating film so as to cover the semiconductor film, and includes a first contact hole overlapping a portion of the semiconductor film in plan view; and a sensor element electrically coupled to the drain electrode, wherein a first electrode, which is one electrode of the source electrode and the drain electrode, overlaps the gate electrode in plan view and is electrically coupled to the semiconductor film in the first contact hole, and in the first contact hole, the first electrode and the semiconductor film face a first partial surface on a side surface of the first contact hole while being separated from the first partial surface.

### BRIEF DESCRIPTION OF THE DRAWINGS

FIG. 1 is a plan view of a detection device according to an embodiment of the present disclosure;

FIG. 2 is a diagram illustrating a circuit configuration of the detection device;

FIG. 3 is a plan view of one sensor element;

FIG. 4 is a sectional view of the detection device taken along IV-IV′ illustrated in FIG. 3;

FIG. 5 is a sectional view of the detection device according to a modification of the embodiment of the present disclosure; and

FIG. 6 is a sectional view of the detection device according to another modification of the embodiment of the present disclosure.

### DETAILED DESCRIPTION

The following describes an embodiment of the present disclosure with reference to the drawings. The present disclosure is not limited to the description of the embodiment to be given below. Components to be described below include those easily conceivable by those skilled in the art or those substantially identical thereto. In addition, the components to be described below can be combined as appropriate.

What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same element as that illustrated in a drawing that has already been discussed is denoted by the same reference numeral through the description and the drawings, and detailed description thereof may not be repeated where appropriate.

An X direction and a Y direction illustrated in the drawings correspond to directions parallel to a plate surface (front surface) of a substrate 40 included in a detection device 1. A +X side and a −X side in the X direction and a +Y side and a −Y side in the Y direction correspond to lateral sides of the detection device 1. A Z direction corresponds to a thickness direction of the detection device 1. A +Z side in the Z direction corresponds to a front side of the detection device 1, and a −Z side in the Z direction corresponds to a back side of the detection device 1. In this specification, “plan view” refers to viewing the detection device 1 from the +Z side toward the −Z side along the Z direction. The X, Y, and Z directions are exemplary, and the present disclosure is not limited to these directions.

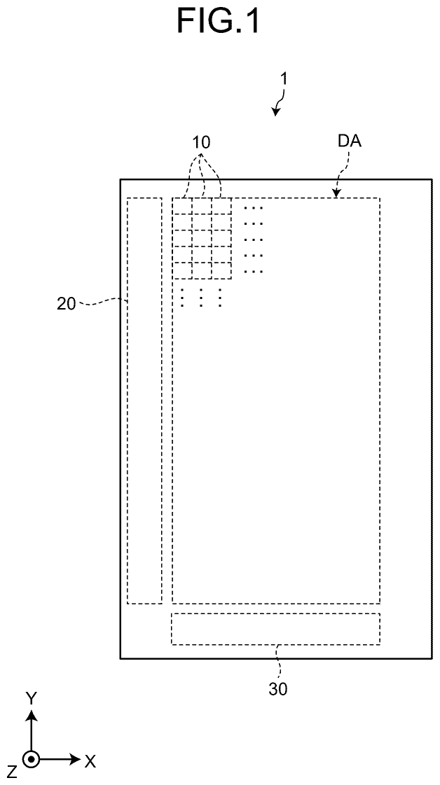

FIG. 1 is a plan view of the detection device 1 according to the embodiment of the present disclosure. The detection device 1 detects predetermined information on an object to be detected. Examples of the object to be detected include, but are not limited to, fingers and thumbs of a user. Examples of the predetermined information include, but are not limited to, asperities on surfaces of the fingers, the thumbs, and palms of the user. The predetermined information may also be biometric information on the user. Examples of the biometric information include, but are not limited to, vascular patterns, fingerprint patterns, pulse waves, pulsation, and blood oxygen saturation levels. The detection device 1 is electrically coupled to a control device that drives the detection device 1.

The detection device 1 has a plate shape. The front surface of the detection device 1 has a detection area DA that makes contact with the object to be detected. In plan view, a plurality of sensor elements 10 are arranged in a matrix having a row-column configuration along the X and Y directions in the detection area DA.

The detection device 1 includes a gate line drive circuit 20 and a signal line selection circuit 30 at locations away from the detection area DA in plan view.

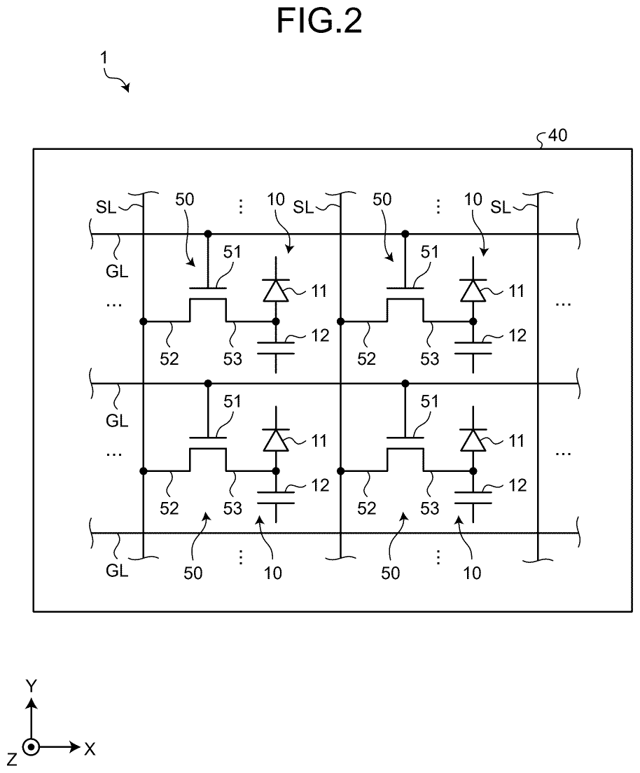

FIG. 2 is a diagram illustrating a circuit configuration of the detection device 1. The detection device 1 includes the substrate 40 and a plurality of gate lines GL and a plurality of signal lines SL arranged on the substrate 40.

The gate lines GL extend along the X direction and are arranged along the Y direction. The gate lines GL are electrically coupled to the gate line drive circuit 20.

The signal lines SL extend along the Y direction and are arranged along the X direction. The signal lines SL are electrically coupled to the signal line selection circuit 30. The signal line selection circuit 30 is a multiplexer, for example. Titanium (Ti), aluminum (Al), copper (Cu), silver (Ag), molybdenum (Mo), or an alloy of these metals is used as the gate lines GL and the signal lines SL.

In plan view, a portion surrounded by two adjacent ones of the gate lines GL and two adjacent ones of the signal lines SL includes a corresponding one of the sensor elements 10.

The sensor element 10 is an optical sensor. The sensor element 10 includes a photodiode 11 and a capacitive element 12.

The photodiode 11 outputs a signal corresponding to light with which the detection area DA is irradiated. The photodiode 11 is a positive-intrinsic-negative (PIN) photodiode, for example.

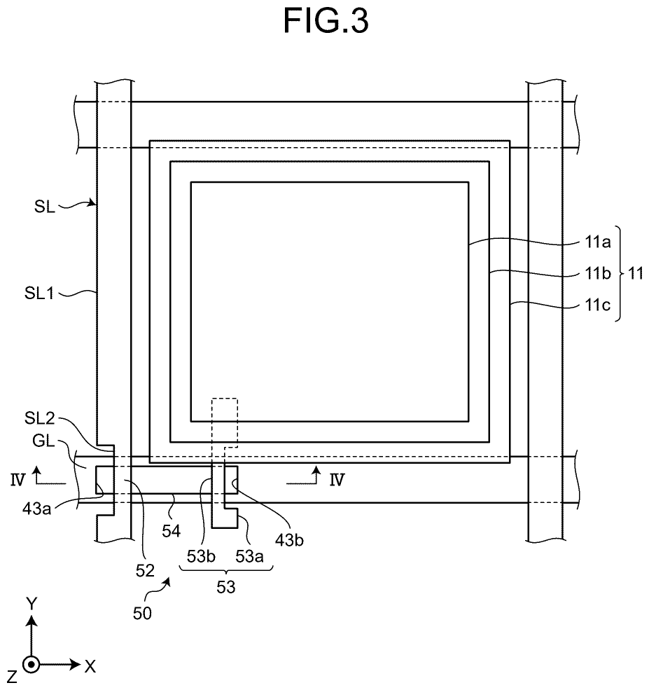

FIG. 3 is a plan view of one of the sensor elements 10.

The photodiode 11 includes an upper electrode 11a, a first semiconductor film 11b, and a lower electrode 11c. The upper electrode 11a, the first semiconductor film 11b, and the lower electrode 11c are stacked in this order from the +Z side toward the −Z side along the Z direction. The upper electrode 11a, the first semiconductor film 11b, and the lower electrode 11c are rectangular in plan view, but, needless to say, are not limited to this shape.

The upper electrode 11a corresponds to a cathode electrode of the photodiode 11. The upper electrode 11a is a light-transmitting conductive layer of, for example, indium tin oxide (ITO).

Examples of the first semiconductor film 11b include, but are not limited to, an i-type semiconductor film, a p-type semiconductor film, and an n-type semiconductor film that are formed of amorphous silicon (a-Si), etc. The n-type semiconductor film, the i-type semiconductor film, and the p-type semiconductor film are stacked in this order along the Z direction.

The lower electrode 11c corresponds to an anode electrode of the photodiode 11. A metal material such as molybdenum (Mo) or aluminum (Al) is used as the lower electrode 11c. The lower electrode 11c may alternatively be a multilayered film formed of a plurality of layers of these metal materials. The lower electrode 11c may be a light-transmitting conductive layer of, for example, ITO or indium zinc oxide (IZO).

The capacitive element 12 illustrated in FIG. 2 is capacitance (sensor capacitance) generated in the photodiode 11.

As illustrated in FIGS. 2 and 3, the detection device 1 further includes a plurality of switching elements 50. Each of the switching elements 50 is electrically coupled to the sensor element 10. The switching element 50 is a transistor. As illustrated in FIG. 2, a gate electrode 51 of the switching element 50 is electrically coupled to each of the gate lines GL. A source electrode 52 (corresponding to “one electrode”) of the switching element 50 is electrically coupled to each of the signal lines SL. A drain electrode 53 (corresponding to “another electrode”) of the switching element 50 is electrically coupled to the anode electrode (lower electrode 11c) and the capacitive element 12 of the photodiode 11.

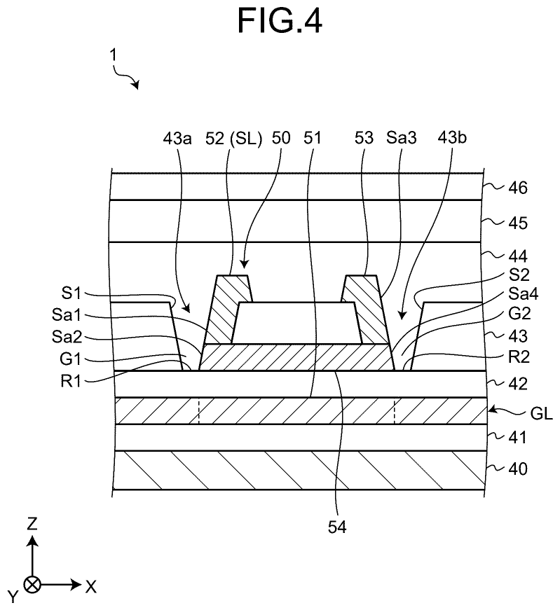

FIG. 4 is a sectional view of the detection device 1 taken along IV-IV illustrated in FIG. 3.

The switching element 50 is disposed on the substrate 40. The switching element 50 is specifically an n-channel metal oxide semiconductor (MOS) thin-film transistor (TFT). The switching element 50 further includes a second semiconductor film 54 (corresponding to “semiconductor film”) that is electrically coupled to the source electrode 52 and the drain electrode 53.

As illustrated in FIGS. 3 and 4, the second semiconductor film 54 has a belt shape that extends along the X direction and overlaps the gate line GL in plan view. As illustrated in FIG. 4, a first insulating layer 41 is disposed on the front surface of the substrate 40, and the gate line GL is disposed on the front surface of the first insulating layer 41. A second insulating layer 42 (corresponding to “first insulating film”) is disposed on the front surface of the first insulating layer 41 so as to cover the gate line GL.

The second semiconductor film 54 is disposed on the front surface of the second insulating layer 42. In other words, the second insulating layer 42 is disposed between the gate line GL and the second semiconductor film 54.

The second semiconductor film 54 is an oxide semiconductor. The second semiconductor film 54 is more preferably a transparent amorphous oxide semiconductor (TAOS) among types of the oxide semiconductor. The second semiconductor film 54 may be formed of, for example, a microcrystalline oxide semiconductor, an amorphous oxide semiconductor, polysilicon, or low-temperature polycrystalline silicon (LTPS).

A portion of the gate line GL that overlaps the second semiconductor film 54 in plan view serves as the gate electrode 51. A channel region is formed at a portion of the second semiconductor film 54 that overlaps the gate line GL (gate electrode 51).

A third insulating layer 43 (corresponding to “second insulating film”) is disposed on the front surface of the second insulating layer 42 so as to cover the second semiconductor film 54. The third insulating layer 43 has a first contact hole 43a and a second contact hole 43b. In the present disclosure, the first contact hole 43a and the second contact hole 43b refer to recesses or through-holes in the third insulating layer 43.

The first contact hole 43a and the second contact hole 43b are arranged along the X direction. The first contact hole 43a and the second contact hole 43b each overlap a portion of the second semiconductor film 54 in plan view.

Specifically, the first contact hole 43a overlaps an end on the −X side of the second semiconductor film 54 in plan view. In other words, the end on the −X side of the second semiconductor film 54 is located inside the first contact hole 43a. The second contact hole 43b overlaps an end on the +X side of the second semiconductor film 54 in plan view. In other words, the end on the +X side of the second semiconductor film 54 is located inside the second contact hole 43b.

The source electrode 52 is disposed in the third insulating layer 43. The source electrode 52 is a portion of the signal line SL and includes a portion electrically coupled to the second semiconductor film 54. Specifically, the source electrode 52 is a portion of the signal line SL that overlaps the second semiconductor film 54 in plan view. The source electrode 52 overlaps the gate line GL in plan view. The source electrode 52 is located opposite the gate electrode 51 with the second semiconductor film 54 interposed therebetween. The source electrode 52 is electrically coupled to the second semiconductor film 54 inside the first contact hole 43a.

In the first contact hole 43a, the source electrode 52 and the second semiconductor film 54 face a first partial surface S1 on a side surface of the first contact hole 43a while being separated therefrom. The first partial surface S1 is a portion of the side surface of the first contact hole 43a. The bottom surface of the first contact hole 43a has a first region R1 that overlaps neither the second semiconductor film 54 nor the source electrode 52 in plan view.

In the first contact hole 43a, the source electrode 52 has a first facing surface Sa1 that faces the first partial surface S1 on the side surface of the first contact hole 43a while being separated therefrom. In the first contact hole 43a, the second semiconductor film 54 has a second facing surface Sa2 that faces the first partial surface S1 on the side surface of the first contact hole 43a while being separated therefrom. The first facing surface Sa1 and the second facing surface Sa2 are each planar. The first facing surface Sa1 and the second facing surface Sa2 are continuous. The first facing surface Sa1 and the second facing surface Sa2 are located in the same plane.

In the first contact hole 43a, a first gap G1 that overlaps the first region R1 in plan view is located between the first facing surface Sa1 and the second facing surface Sa2 and the first partial surface S1 on the side surface of the first contact hole 43a.

The first gap G1 and the first region R1 are not present before an etching process in which the source electrode 52 is formed. At that time, the material of the second semiconductor film 54 and the material of the source electrode 52 are stacked in the first contact hole 43a. In the etching process in which the source electrode 52 is formed, the material of the second semiconductor film 54 is partially removed when a portion of the material of the source electrode 52 to which no resist is applied is removed. This process forms the first gap G1 and the first region R1, and forms the first facing surface Sa1 and the second facing surface Sa2 that are separated from the first partial surface S1 on the side surface of the first contact hole 43a.

As illustrated in FIG. 3, the signal line SL has a first signal portion SL1 and a second signal portion SL2. The second signal portion SL2 has a smaller width than that of the first signal portion SL1. The second signal portion SL2 is a portion that includes the source electrode 52 and overlaps the second semiconductor film 54 and the gate electrode 51 (gate line GL) in plan view.

The drain electrode 53 is a belt-shaped electrode that extends along the Y direction on the +X side of the source electrode 52. An end on the +Y side of the drain electrode 53 is electrically coupled to the lower electrode 11c of the sensor element 10. The drain electrode 53 has a first drain portion 53a and a second drain portion 53b. The second drain portion 53b has a smaller width than that of the first drain portion 53a. The second drain portion 53b is a portion that overlaps the second semiconductor film 54 and the gate electrode 51 (gate line GL) in plan view.

As illustrated in FIG. 4, the drain electrode 53 is disposed in the third insulating layer 43. The drain electrode 53 overlaps the gate line GL in plan view. The drain electrode 53 is located on the opposite side of the gate electrode 51 with the second semiconductor film 54 interposed therebetween. The drain electrode 53 is electrically coupled to the second semiconductor film 54 inside the second contact hole 43b.

In the second contact hole 43b, the drain electrode 53 and the second semiconductor film 54 face a second partial surface S2 on a side surface of the second contact hole 43b while being separated therefrom. The second partial surface S2 is a portion of the side surface of the second contact hole 43b. The bottom surface of the second contact hole 43b has a second region R2 that overlaps neither the second semiconductor film 54 nor the drain electrode 53 in plan view.

In the second contact hole 43b, the drain electrode 53 has a third facing surface Sa3 that faces the second partial surface S2 of the side surface of the second contact hole 43b while being separated therefrom. In the second contact hole 43b, the second semiconductor film 54 has a fourth facing surface Sa4 that faces the second partial surface S2 of the side surface of the second contact hole 43b while being separated therefrom. The third facing surface Sa3 and the fourth facing surface Sa4 are continuous. The third facing surface Sa3 and the fourth facing surface Sa4 are each planar. The third facing surface Sa3 and the fourth facing surface Sa4 are located in the same plane.

In the second contact hole 43b, a second gap G2 that overlaps the second region R2 in plan view is located between the third facing surface Sa3 and the fourth facing surface Sa4 and the second partial surface S2 on the side surface of the second contact hole 43b.

The second gap G2 and the second region R2 are not present before the etching process in which the drain electrode 53 is formed. At that time, the material of the second semiconductor film 54 and the material of the drain electrode 53 are stacked in the second contact hole 43b. In the etching process in which the drain electrode 53 is formed, the material of the second semiconductor film 54 is partially removed when a portion of the material of the drain electrode 53 to which no resist is applied is removed. This process forms the second gap G2 and the second region R2, and forms the third facing surface Sa3 and the fourth facing surface Sa4 that are separated from the second partial surface S2 on the side surface of the second contact hole 43b.

A fourth insulating layer 44 is disposed on the front surface of the third insulating layer 43 so as to cover the source electrode 52 and the drain electrode 53. The fourth insulating layer 44 is also located in the first gap G1 and the second gap G2. Inorganic insulating films are used as the first insulating layer 41, the second insulating layer 42, the third insulating layer 43, and the fourth insulating layer 44. The inorganic insulating films are formed of, for example, silicon oxide (SiO₂) or silicon nitride (SiN). Each of the inorganic insulating films is not limited to one film, and may be a plurality of stacked films.

A fifth insulating layer 45 is disposed on the front surface of the fourth insulating layer 44, and a sealing film 46 is disposed on the front surface of the fifth insulating layer 45. The photodiode 11 is disposed between the fourth insulating layer 44 and the fifth insulating layer 45.

The fifth insulating layer 45 and the sealing film 46 are each made using an inorganic film such as a silicon nitride film or an aluminum oxide film, or a resin film of acrylic or the like. Each of the fifth insulating layer 45 and the sealing film 46 is not limited to one film, and may be a plurality of stacked films obtained by combining the inorganic films and the resin films described above.

The following describes an operation of the detection device 1.

Light reflected by the object to be detected or light transmitted through the object to be detected enters the detection area DA of the detection device 1. When the sensor element 10 is irradiated with the light, a current corresponding to the amount of the light flows through the photodiode 11, and an electric charge is stored in the capacitive element 12. The control device controls the gate line drive circuit 20 to sequentially select the gate lines GL. When the selected switching element 50 is turned on, a current corresponding to the electric charge stored in the capacitive element 12 flows through the signal line SL in the sensor element 10 corresponding to the turned-on switching element 50. The signal line SL is coupled to the control device via the signal line selection circuit 30. With this configuration, the detection device 1 detects a signal corresponding to the amount of the light with which the photodiode 11 is irradiated for each of the sensor elements 10. The control device generates the predetermined information on the object to be detected (for example, the fingerprint patterns of the user) based on the signal.

As described above, in the first contact hole 43a, the source electrode 52 and the second semiconductor film 54 face the first partial surface S1 on the side surface of the first contact hole 43a while being separated therefrom. This configuration reduces the area of overlapping between the source electrode 52 and the gate electrode 51 in plan view and the capacitance between the source electrode 52 and the gate electrode 51 compared with a case where the source electrode 52 is in contact with the first partial surface S1 on the side surface of the first contact hole 43a and the first gap G1 is not present. Therefore, noise generated by the capacitance between the source electrode 52 and the gate electrode 51 can be restrained from affecting the sensor element 10.

In the second contact hole 43b, the drain electrode 53 and the second semiconductor film 54 face the second partial surface S2 on the side surface of the second contact hole 43b while being separated therefrom. This configuration reduces the area of overlapping between the drain electrode 53 and the gate electrode 51 in plan view and the capacitance between the drain electrode 53 and the gate electrode 51 compared with a case where the drain electrode 53 is in contact with the second partial surface S2 on the side surface of the second contact hole 43b and the second gap G2 is not present. Therefore, noise generated by the capacitance between the drain electrode 53 and the gate electrode 51 can be restrained from affecting the sensor element 10.

While the preferred embodiment of the present disclosure has been described above, the present disclosure is not limited to the embodiment described above. The content disclosed in the embodiment is merely an example, and can be variously modified within the scope not departing from the gist of the present disclosure. Any modifications appropriately made within the scope not departing from the gist of the present disclosure also naturally belong to the technical scope of the present disclosure.

For example, in the photodiode 11, the upper electrode 11a may correspond to the anode electrode. In this case, the lower electrode 11c of the photodiode 11 corresponds to the cathode electrode.

The first facing surface Sa1 and the second facing surface Sa2 may be curved surfaces. The first facing surface Sa1 and the second facing surface Sa2 need not be located in the same plane.

In the second contact hole 43b, the third facing surface Sa3 and the fourth facing surface Sa4 may be in contact with the second partial surface S2 on the side surface of the second contact hole 43b.

The width of the signal line SL may be constant. The width of the drain electrode 53 may be constant.

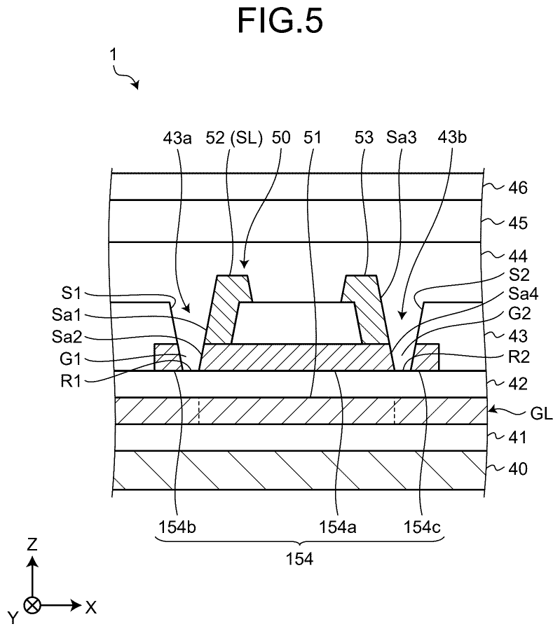

FIG. 5 is a sectional view of the detection device 1 according to a modification of the embodiment of the present disclosure. In the present modification, a second semiconductor film 154 includes a first partial film 154a, a second partial film 154b, and a third partial film 154c. The first partial film 154a, the second partial film 154b, and the third partial film 154c are separate films.

The first partial film 154a corresponds to the second semiconductor film 54 of the embodiment described above. That is, the first partial film 154a has the second facing surface Sa2 and the fourth facing surface Sa4 and is electrically coupled to the source electrode 52 and the drain electrode 53.

The second partial film 154b and the third partial film 154c are portions that are electrically separated from the first partial film 154a and overlap the third insulating layer 43 in plan view.

Specifically, the second partial film 154b is located on the opposite side of the first partial film 154a with the first contact hole 43a interposed therebetween in the X direction. The third partial film 154c is located on the opposite side of the first partial film 154a with the second contact hole 43b interposed therebetween in the X direction.

Before the etching process in which the source electrode 52 and the drain electrode 53 are formed, the material of the second semiconductor film 154 is one member having portions connecting the first partial film 154a to the second partial film 154b and the second partial film 154b to the third partial film 154c. The etching process removes the connecting portions. Thereby, the material of the second semiconductor film 154 is divided to form the second semiconductor film 154 that includes the first partial film 154a, the second partial film 154b, and the third partial film 154c.

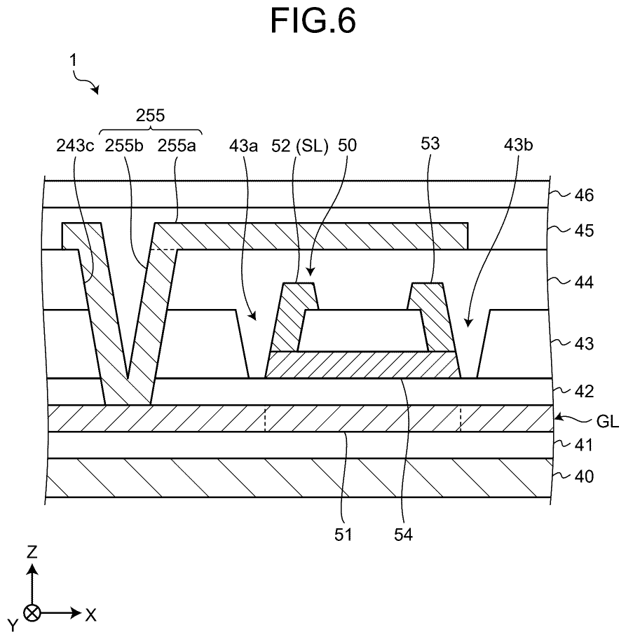

FIG. 6 is a sectional view of the detection device 1 according to another modification of the embodiment of the present disclosure. In the present modification, the detection device 1 further includes a second gate electrode 255. The second gate electrode 255 includes a body 255a and a coupler 255b in one piece.

The body 255a is disposed between the fourth insulating layer 44 and the fifth insulating layer 45. The body 255a is located on the opposite side of the gate electrode 51 with the second semiconductor film 54, the source electrode 52, and the drain electrode 53 interposed therebetween. The body 255a overlaps the second semiconductor film 54, the source electrode 52, the drain electrode 53, and the gate electrode 51 in plan view.

The coupler 255b is located on the −X side of the signal line SL and electrically coupled to the gate electrode 51 through a third contact hole 243c.

The second gate electrode 255 reduces generation of noise in the switching element 50 when X-rays enter the detection area DA.

By arranging the source electrode 52 and the drain electrode 53 in the same way as in the embodiment described above, the sensor element 10 is restrained from being affected by noise generated by capacitance between the gate electrode 51 and the second gate electrode 255, and the source electrode 52 and noise generated by capacitance between the gate electrode 51 and the second gate electrode 255, and the drain electrode 53.

Other operational advantages accruing from the aspects described in the above-described embodiment that are obvious from the description herein, or that are conceivable as appropriate by those skilled in the art will naturally be understood as accruing from the present disclosure.

What is claimed is:

1. A detection device comprising:
a substrate;
a switching element disposed on the substrate, the switching element comprising a source electrode, a drain electrode, a semiconductor film electrically coupled to the source and the drain electrodes, and a gate electrode disposed on an opposite side of the source and the drain electrodes with the semiconductor film interposed between the gate electrode and the source and the drain electrodes;
a first insulating film disposed between the gate electrode and the semiconductor film;
a second insulating film that is disposed on the first insulating film so as to cover the semiconductor film, and comprises a first contact hole overlapping a portion of the semiconductor film in plan view; and
a sensor element electrically coupled to the drain electrode, wherein
a first electrode, which is one electrode of the source electrode and the drain electrode, overlaps the gate electrode in plan view and is electrically coupled to the semiconductor film in the first contact hole, and
in the first contact hole, the first electrode and the semiconductor film face a first partial surface on a side surface of the first contact hole while being separated from the first partial surface.

2. The detection device according to claim 1, wherein
the first electrode has a first facing surface that faces the first partial surface on the side surface of the first contact hole in the first contact hole while being separated from the first partial surface,
the semiconductor film has a second facing surface that faces the side surface of the first contact hole in the first contact hole while being separated from the side surface of the first contact hole, and
the first facing surface and the second facing surface are continuous.

3. The detection device according to claim 1, wherein
the second insulating film further comprises a second contact hole that overlaps another portion of the semiconductor film in plan view,
a second electrode, which is other electrode of the source electrode and the drain electrode, overlaps the gate electrode in plan view and is electrically coupled to the semiconductor film in the second contact hole, and
in the second contact hole, the second electrode and the semiconductor film face a second partial surface on a side surface of the second contact hole while being separated from the second partial surface.

4. The detection device according to claim 1, wherein
the semiconductor film comprises:
a first partial film electrically coupled to the first electrode; and
a second partial film that is electrically separated from the first partial film and overlaps the second insulating film in plan view.
